(19) United States
(12) Patent Application Publication
(10) Pub. No.: US 2025/0386634 A1
(43) Pub. Date: Dec. 18, 2025

(54) DISPLAY DEVICE, METHOD OF MANUFACTURING THE DISPLAY DEVICE, AND ELECTRONIC DEVICE INCLUDING THE DISPLAY DEVICE

(71) Applicant: Samsung Display Co., Ltd., Yongin-Si (KR)

(72) Inventors: SUN WOO LEE, Yongin-si (KR); RAN KIM, Yongin-si (KR); SE-JIN PARK, Yongin-si (KR); YOUNGGIL PARK, Yongin-si (KR)

(21) Appl. No.: 19/063,291

(22) Filed: Feb. 26, 2025

(30) Foreign Application Priority Data
Jun. 13, 2024 (KR) 10-2024-0076753

(51) Int. Cl. H10H 29/32; H10H 29/01; H10H 29/14; H10H 29/49; H10H 29/855

(52) U.S. Cl. CPC H10H 29/32; H10H 29/012; H10H 29/142; H10H 29/49; H10H 29/855

(57) ABSTRACT

A display device includes a substrate including a light emitting area and a driving area spaced apart from the light emitting area in a plan view, a first epi layer disposed in the light emitting area on the substrate, a light emitting diode disposed in the light emitting area and disposed on the first epi layer, a second epi layer disposed in the driving area on the substrate, a transistor disposed in the driving area and on the second epi layer, and a connection electrode that electrically connects the light emitting diode and the transistor.

### CROSS-REFERENCE TO RELATED APPLICATION

This application claims priority to Korean Patent Application No. 10-2024-0076753, filed on Jun. 13, 2024, and all the benefits accruing therefrom under 35 U.S.C. § 119, the content of which in its entirety is herein incorporated by reference.

### BACKGROUND

### Field

The present disclosure relates to a display device, a method of manufacturing the display device, and an electronic device including the display device. More specifically, the present disclosure relates a display device that provides display information, method of manufacturing the display device, and the electronic device including the display device.

### Discussion of the Background

Current display devices include liquid crystal displays (LCD), organic light emitting diode (OLED) displays, and quantum dot light emitting diode (QLED) displays to name a few. Among these display devices, market interest has recently grown in micro light emitting diode displays, and efforts to improve productivity and efficiency for producing such display devices are continuing.

### SUMMARY

One purpose of the present disclosure is to disclose display devices that provide increased manufacturing productivity and lower costs.

Another purpose of the present disclosure is to disclose a method of manufacturing the display devices.

Still another purpose of the present disclosure is to disclose an electronic device including the display device.

A display device according to an embodiment of the present disclosure includes a substrate including a light emitting area and a driving area spaced apart from the light emitting area in a plan view, a first epi layer disposed in the light emitting area on the substrate, a light emitting diode disposed in the light emitting area and disposed on the first epi layer, a second epi layer disposed in the driving area on the substrate, a transistor disposed in the driving area and on the second epi layer, and a connection electrode that electrically connects the light emitting diode and the transistor.

In an embodiment, the display device may further include a metal electrode disposed on the light emitting diode and electrically connected to the light emitting diode. The connection electrode may be connected to the metal electrode.

In an embodiment, the light emitting diode may include a first semiconductor layer, a quantum well layer, and a second semiconductor layer. The first semiconductor layer may be an n-type semiconductor, and the second semiconductor layer may be a p-type semiconductor.

In an embodiment, the display device may further include a germanium layer disposed between the second epi layer and the transistor.

In an embodiment, the transistor may include an active layer disposed on the germanium layer, and a lattice constant of the germanium layer may be greater than a lattice constant of the active layer.

In an embodiment, the active layer may be disposed lower than the quantum well layer of the light emitting diode in a cross-sectional view.

In an embodiment, the light emitting diode and the active layer may be spaced apart from each other in a plan view.

In an embodiment, the display device may further include a light barrier disposed between the light emitting diode and the transistor in a plan view.

In an embodiment, the light barrier may be disposed on the substrate at a same level as the light emitting diode.

In an embodiment, the substrate may include at least one of silicon, silicon germanium, silicon carbide, and sapphire.

In an embodiment, the first epi layer and the second epi layer may include silicon.

In an embodiment, the first epi layer and the second epi layer may be disposed at a same level on the substrate.

A method of manufacturing the display device according to an embodiment of the present disclosure includes forming a first insulating layer on a substrate including a light emitting area and a driving area spaced apart from the light emitting area in a plan view, exposing an upper surface of the substrate in the light emitting area and the driving area by etching the first insulating layer, forming a first epi layer on the upper surface of the substrate in the light emitting area and forming a second epi layer on the upper surface of the substrate exposed in the driving area, forming a transistor on the second epi layer, and forming a light emitting diode on the first epi layer.

In an embodiment, the method may further include after forming the light emitting diode on the first epi layer, forming a connection electrode that electrically connects the light emitting diode and the transistor.

In an embodiment, the first epi layer and the second epi layer may be formed together in a same process.

In an embodiment, forming the first epi layer in the light emitting area and forming the second epi layer in the driving area may include depositing the first epi layer in the light emitting area and depositing the second epi layer in the driving area, forming a second insulating layer covering the first epi layer and the second epi layer, and polishing the second insulating layer to expose the first epi layer and the second epi layer from the second insulating layer.

In an embodiment, the method may further include after forming the second epi layer and before forming the transistor, forming a germanium layer on the second epi layer.

In an embodiment, the germanium layer may be formed by epitaxial growth on the second epi layer.

In an embodiment, the method may further include after forming a transistor on the second epi layer, forming a light barrier between the light emitting area and the driving area in a plan view.

In an embodiment, forming the light emitting diode may include epitaxial growth on the first epi layer, and forming the transistor may include epitaxial growth on the second epi layer.

An electronic device according to an embodiment of the present disclosure includes a display device and a processor configured to drive the display device, and wherein the display device includes a substrate including a light emitting area and a driving area spaced apart from the light emitting area in a plan view, a first epi layer disposed in the light emitting area on the substrate, a light emitting diode disposed in the light emitting area and disposed on the first epi layer, a second epi layer disposed in the driving area on the substrate, a transistor disposed in the driving area and on the second epi layer, and a connection electrode that electrically connects the light emitting diode and the transistor.

A display device according to an embodiment of the present disclosure may include a substrate including a light emitting area and a driving area spaced apart from the light emitting area in a plan view, a first epi layer disposed in the light emitting area on the substrate, a light emitting diode disposed in the light emitting area and disposed on the first epi layer, a second epi layer disposed in the driving area on the substrate, a transistor disposed in the driving area and on the second epi layer, and a connection electrode that electrically connects the light emitting diode and the transistor.

According to an aspect of the present disclosure, a transfer process may not be required when forming the display device. That is, by forming the light emitting diode and the transistor through a deposition process on the substrate, the transfer process that forms the light emitting diode or the transistor and transfers the formed structure to the substrate may be omitted, thereby reducing process cost and process time. As a result, the display device may provide improved manufacturing productivity or reduced costs.

Additionally, the light emitting diode and the transistor may be disposed at substantially the same level on the substrate. Accordingly, a thickness of the display device may be thinner compared to a case where the light emitting diode is disposed on the transistor.

### BRIEF DESCRIPTION OF THE DRAWINGS

The accompanying drawings, which are included to provide a further understanding of this specification, illustrate embodiments in accordance with the present disclosure.

FIG. 1 is a perspective view showing a display device according to an embodiment of the present disclosure.

FIG. 2 is a plan view of the display device of FIG. 1.

FIG. 3 is a cross-sectional view taken along line I-I′ of FIG. 2.

FIG. 4 is an enlarged plan view of area A of FIG. 2.

FIGS. 5, 6, 7, 8, 9, 10, 11, 12, 13, 14, 15, and 16 are cross-sectional views of structures formed during an embodiment of a method of manufacturing the display device of FIG. 3.

FIG. 17 is block-diagram for showing an electronic device according to an embodiment of the disclosure.

FIG. 18 is schematic views for showing the electronic device according to various embodiments of FIG. 17.

### DETAILED DESCRIPTION

Illustrative, non-limiting embodiments will be more clearly understood from the following detailed description in conjunction with the accompanying drawings.

In this specification, a plane may be defined by a first direction D1 and a second direction D2 at a non-zero angle to the first direction D1. For example, the second direction D2 may be perpendicular to the first direction D1. In addition, a third direction D3 may be a normal direction of the plane defined by the first direction D1 and the second direction D2. For example, the third direction D3 may be perpendicular to the first direction D1 and the second direction D2.

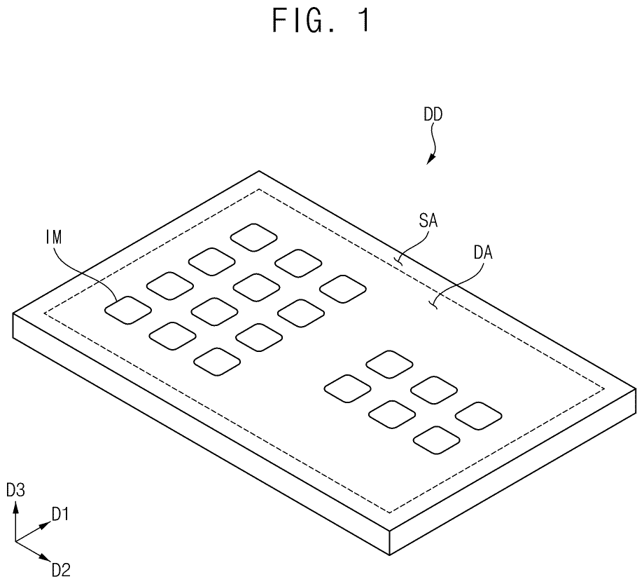

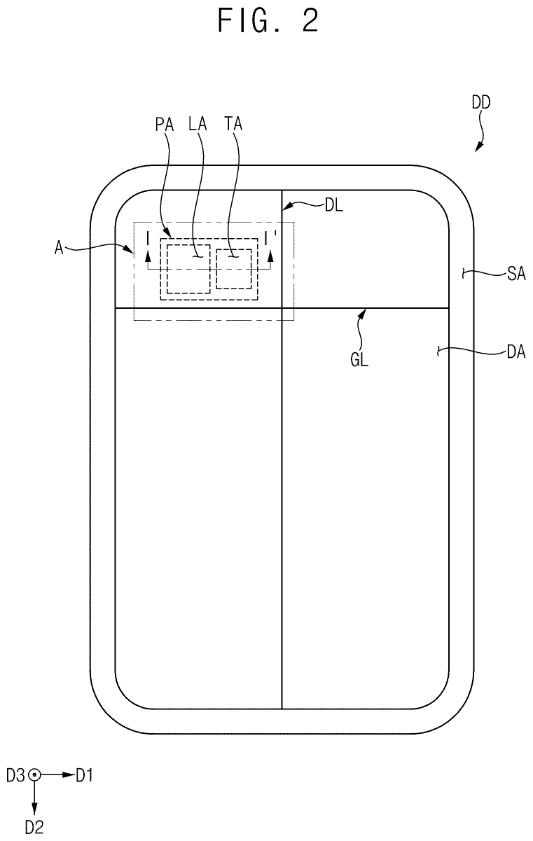

FIG. 1 shows a perspective view of a display device according to an embodiment of the present disclosure. FIG. 2 shows a plan view of the display device of FIG. 1.

Referring to FIGS. 1 and 2, a display device DD may include a display area DA and a peripheral area SA. The display area DA may be surrounded by the peripheral area SA. The display area DA may be an area that may display an image by generating light or adjusting a transmittance of light from a light source. The peripheral area SA may be an area that does not display an image. However, embodiments of the present disclosure are not necessarily limited thereto, and at least a portion of the peripheral area SA may display an image.

The display area DA may display images IM. Users may receive information from the display device DD through the images IM.

In an embodiment, the display device DD may be an ultra-small LED display device (or micro LED display device) that includes ultra-small LEDs (or micro LEDs) as light emitting diodes. However, the present disclosure is not necessarily limited thereto.

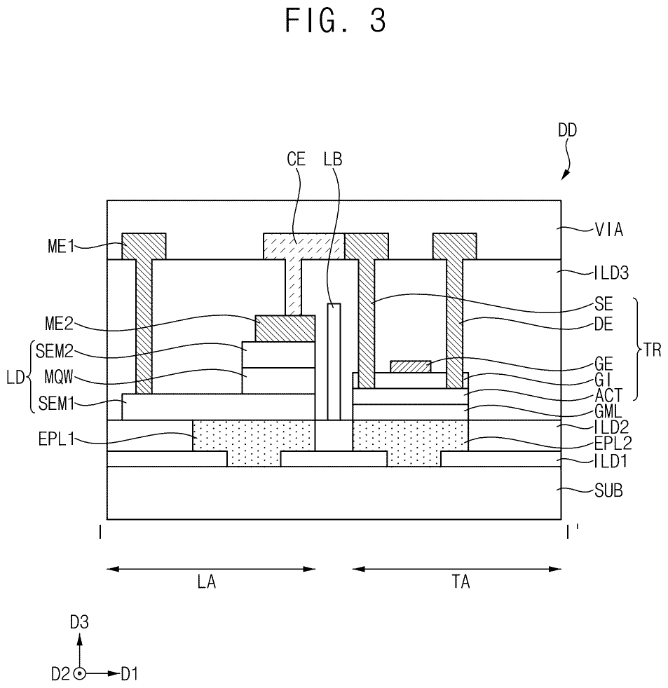

The display area DA of the display device DD may include a pixel area PA or an array of pixel areas PA. Each pixel area PA may have a generally rectangular shape that extends in the first direction D1 and the second direction D2. Each pixel area PA may include a light emitting area LA in which a light emitting diode (e.g., a light emitting diode LD in FIG. 3) is disposed and may include a driving area TA in which a transistor (e.g., a transistor TR in FIG. 3) is disposed.

In an embodiment, the light emitting area LA and the driving area TA may be spaced apart from each other in a plan view. That is, the light emitting area LA and the driving area TA may not overlap in a plan view. In FIG. 2, the light emitting area LA is shown to be disposed to a left side of the driving area TA in a plan view, but the embodiments of the present disclosure are not necessarily limited thereto. The light emitting area LA may be disposed to a right side of the driving area TA or above or below the driving area TA. FIG. 2 shows an example in which the light emitting area LA and the driving area TA are spaced apart from each other in the first direction D1. However, embodiments of the present disclosure are not necessarily limited thereto. The light emitting area LA and the driving area TA may be spaced apart from each other in the second direction D2. In these cases, the light emitting area LA and the driving area TA may not overlap in a plan view and may be spaced apart within the pixel area PA.

The display device DD may include gate lines GL and data lines DL.

The gate lines GL may extend in the first direction D1. In FIG. 2, only one gate line of the gate lines GL is shown, but the display device DD may include a plurality of the gate lines GL, which may be spaced from each other in the second direction D2. The gate lines GL may apply gate signals to one or more transistors (e.g., the transistor TR of FIG. 3) each driving area TA.

The data lines DL may extend in the second direction D2. In FIG. 2, only one data line of the data lines DL is shown, but the display device DD may include a plurality of the data lines DL, which may be spaced from each other in the first direction D1. The data lines DL may apply data signals to one or more transistors (e.g., the transistor TR of FIG. 3) in each driving area TA.

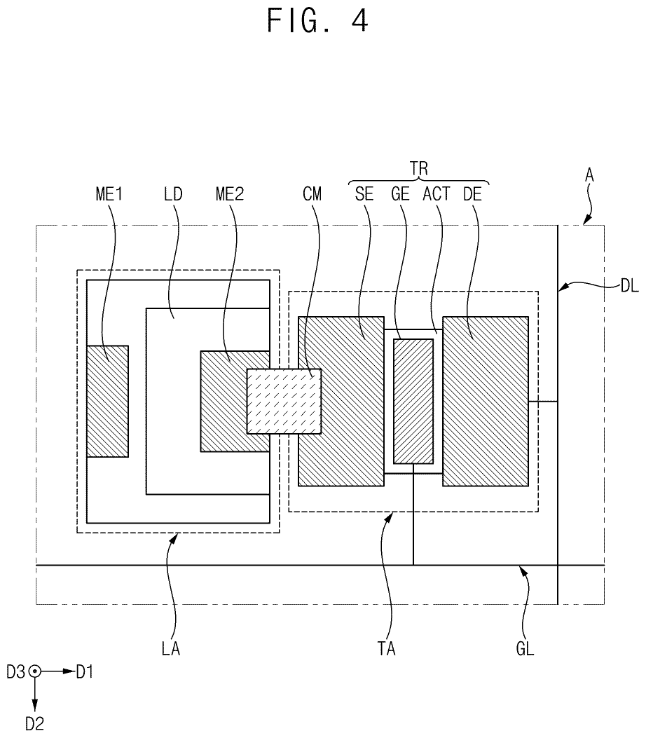

FIG. 3 is a cross-sectional view taken along line I-I′ of FIG. 2. FIG. 4 is an enlarged plan view of area A of FIG. 2.

Referring to FIGS. 3 and 4, the display device DD may include a substrate SUB, first, second, and third insulating layers ILD1, ILD2, and ILD3, a via layer VIA, first and second epilayers EPL1, EPL2, a germanium layer GML, the transistor TR, the light emitting diode LD, a gate isolation pattern GI, first and second metal electrodes ME1, ME2, a connection electrode CE, and a light barrier LB.

The transistor TR may include an active layer ACT, a gate electrode GE, a source electrode SE, and a drain electrode DE. The light emitting diode LD may include a first semiconductor layer SEM1, a quantum well layer MQW, and a second semiconductor layer SEM2.

The substrate SUB may include the light emitting area LA and the driving area TA. The light emitting area LA and the driving area TA may be spaced in the first direction D1. The substrate SUB may support the light emitting diode LD disposed in the light emitting area LA and the transistor TR disposed in the driving area TA. For example, the substrate SUB may include silicon, silicon germanium, silicon carbide, sapphire, potassium arsenic, zinc oxide, and gallium nitride. However, embodiments of the present disclosure are not necessarily limited thereto.

The first insulating layer ILD1 may be disposed on the substrate SUB. The first insulating layer ILD1 may prevent impurities from flowing from the substrate SUB from reaching the light emitting diode LD and/or the transistor TR. The first insulating layer ILD1 may include inorganic insulating materials. For example, the first insulating layer ILD1 may include silicon oxide. The first insulating layer ILD1 may be a buffer layer. However, embodiments of the present disclosure are not necessarily limited thereto.

In an embodiment, the first insulating layer ILD1 may expose at least part of the substrate SUB. For example, at least part of the first insulating layer ILD1 overlapping in a plan view with the light emitting area LA may be etched to expose a top surface of the substrate SUB. In addition, at least part of the first insulating layer ILD1 overlapping with the driving area TA in a plan view may be etched to expose an upper surface of the substrate SUB. Etching the first insulating layer ILD1 to expose an upper surface of the substrate SUB allows the first epi layer EPL1 and the second epi layer EPL2 to be deposited on the upper surface of the substrate SUB.

The first epi layer EPL1 and the second epi layer EPL2 may be disposed on the substrate SUB and the first insulating layer ILD1. Specifically, the first epi layer EPL1 may be disposed on a portion of the upper surface of the substrate SUB exposed by an opening through the first insulating layer ILD1 in the light emitting area LA. The second epi layer EPL2 may be disposed on a portion of the upper surface of the substrate SUB exposed by an opening through the first insulating layer ILD1 in the driving area TA. The first epi layer EPL1 and the second epi layer EPL2 may include substantially the same material (e.g., silicon) as the substrate SUB.

In an embodiment, a lattice structure of each of the first epi layer EPL1 and the second epi layer EPL2 may correspond to a lattice structure of the substrate SUB. That is, a lattice structure of each of the first epi layer EPL1 and the second epi layer EPL2 may correspond to a lattice structure of the substrate SUB because the first epi layer EPL1 and the second epi layer EPL2 are grown epitaxially on the substrate SUB. The first epi layer EPL1 and the second epi layer EPL2 grown epitaxially on the substrate SUB may reduce defects in the light emitting diode LD disposed on the first epi layer EPL1 and the transistor TR disposed on the second epi layer EPL2. Thus, a light emitting efficiency of the light emitting diode and a driving efficiency of the transistor may be improved.

The second insulating layer ILD2 may be disposed on the first insulating layer ILD1. Specifically, the second insulating layer ILD2 may be disposed on the first insulating layer ILD1 and may surround the first epi layer EPL1 and the second epi layer EPL2. The second insulating layer ILD2 may prevent the first epi layer EPL1 and the second epi layer EPL2 from contacting each other. The second insulating layer ILD2 may include substantially the same material as the first insulating layer ILD1.

The light emitting diode LD may be disposed on the first epi layer EPL1. The light emitting diode LD may include an organic light emitting diode or an inorganic light emitting diode. The light emitting diode LD may emit light and provide visual information to a user. The light emitting diode LD may emit red light, green light, blue light, or a combination thereof. However, embodiments of the present disclosure are not necessarily limited thereto.

The first semiconductor layer SEM1 may be disposed on the first epi layer EPL1. The first semiconductor layer SEM1 may include n-type semiconductors. For example, the first semiconductor layer SEM1 may include n-type doped AlGaInN, GaN, AlGaN, InGaN, AlN, and InN. The semiconductor materials may be used alone or in combination with each other. However, embodiments of the present disclosure are not necessarily limited thereto.

The first metal electrode ME1 may be disposed on the first semiconductor layer SEM1. The first metal electrode ME1 may be electrically connected to the first semiconductor layer SEM1. For example, the first metal electrode ME1 may apply an electrical signal to the first semiconductor layer SEM1 so that an electric current may flow to the light emitting diode LD. The first metal electrode ME1 may include metallic materials.

The quantum well layer MQW may be disposed on the first semiconductor layer SEM1. The quantum well layer MQW may generate light when electrons and holes in the quantum well layer MQW combine. The quantum well layer MQW may include a single quantum well structure or multiple quantum well structure. The quantum well layer MQW may include GaN.

The second semiconductor layer SEM2 may be disposed on the quantum well layer MQW. The second semiconductor layer SEM2 may include p-type semiconductors. For example, the second semiconductor layer SEM2 may include p-type doped AlGaInN, GaN, AlGaN, InGaN, AIN, and InN. The semiconductor materials may be used alone or in combination with each other. However, embodiments of the present disclosure are not necessarily limited thereto.

The light emitting diode LD with the structure described above may generate light by combining an electron transmitted from the first semiconductor layer SEM1 and a hole transmitted from the second semiconductor layer SEM2.

The second metal electrode ME2 may be disposed on the second semiconductor layer SEM2. The second metal electrode ME2 may be electrically connected to the second semiconductor layer SEM2. For example, the second metal electrode ME2 may apply an electrical signal to the second semiconductor layer SEM2 so that an electric current may flow to the light emitting diode LD. The second metal electrode ME2 may include metallic materials.

The germanium layer GML may be disposed on the second epi layer EPL2. The germanium layer GML may increase a lattice constant of the active layer ACT. The germanium layer GML, by increasing a lattice constant of the active layer ACT, may increase a mobility of electrons flowing through the active layer ACT. In one example, a lattice constant of the active layer ACT may be about 5.4 angstrom to about 5.5 angstrom, and a lattice constant of the germanium layer GML may be about 5.6 angstrom to about 5.7 angstrom. Optionally, the germanium layer GML may be omitted.

The transistor TR may be disposed on the germanium layer GML. If the germanium layer GML is omitted, the transistor TR may be disposed on the second epi layer EPL2. The transistor TR may transmit a signal to the light emitting diode LD so that the light emitting diode LD may emit light.

The active layer ACT may be disposed on the germanium layer GML. If the germanium layer GML is omitted, the active layer ACT may be disposed on the second epi layer EPL2. The active layer ACT may include a source area, a channel area, and a drain area. The active layer ACT may include oxide semiconductors, silicon semiconductors, organic semiconductors, etc. However, embodiments of the present disclosure are not necessarily limited thereto.

In an embodiment, the active layer ACT may be disposed lower in the layer structure of the display device DD than is the quantum well layer MQW of the light emitting diode LD, as shown in the cross-sectional view of FIG. 3. Light emitted from the quantum well layer MQW may not reach the active layer ACT when the active layer ACT is lower than the quantum well layer MQW. As a result, as the active layer ACT is disposed lower than the quantum well layer MQW of the light emitting diode, a phenomenon of light excitation of the transistor TR may be prevented.

The active layer ACT may be spaced apart from the light emitting diode LD in a plan view. As the active layer ACT is spaced apart from the light emitting diode LD, so that the transistor TR and the light emitting diode LD do not overlap in a plan view.

The gate insulation pattern GI may be disposed on the active layer ACT. The gate insulation pattern GI may prevent the gate electrode GE and the active layer ACT from directly contacting each other. The gate insulation pattern GI may include inorganic insulating materials.

The gate electrode GE may be disposed on the gate insulation pattern GI. The gate electrode GE may include conductive materials such as metals, alloys, conductive metal nitrides, conductive metal oxides, and transparent conductive materials. The conductive materials may be used alone or in combination with each other. Optionally, the gate electrode GE may have a single-layer structure or have a multilayer structure including multiple conductive layers. However, embodiments of the present disclosure are not necessarily limited thereto.

The source electrode SE and the drain electrode DE may be disposed on the active layer ACT. Specifically, the source electrode SE may be electrically connected to the source area of the active layer ACT, and the drain electrode DE may be electrically connected to the drain area of the active layer ACT. Each of the source electrode SE and the drain electrode DE may include a metallic material.

The light barrier LB may be disposed on the second insulating layer ILD2. Specifically, the light barrier LB may be disposed between the light emitting diode LD and the transistor TR in a plan view. The light barrier LB may block the light emitted from the light emitting diode LD and may thereby prevent the light from reaching the active layer ACT of the transistor TR. In other words, the light barrier LB may prevent a light excitation of the transistor TR. The light barrier LB may extend to or past the level or height of the light emitting diode LD on the substrate.

The third insulating layer ILD3 may be disposed on the second insulating layer ILD2. Specifically, the third insulating layer ILD3 may be disposed on the second insulating layer ILD2 and may cover the light emitting diode LD, the gate electrode GE of the transistor TR, and the light barrier LB. The third insulating layer ILD3 may include substantially the same material as the first insulating layer ILD1.

The connection electrode CE may be disposed on the third insulating layer ILD3. The connection electrode CE may be electrically connected to the light emitting diode LD by penetrating the third insulating layer ILD3. Specifically, the connection electrode CE may be connected to the second metal electrode ME2 of the light emitting diode LD. For example, the connection electrode CE may connect the second metal electrode ME2 of the light emitting diode LD and the source electrode SE of the transistor TR, permitting the transistor TR to drive the light emitting diode LD.

The via layer VIA may be disposed on the third insulating layer ILD3. Specifically, the via layer VIA may be disposed on the third insulating layer ILD3 and may cover the connection electrode CE. The via layer VIA may flatten or planarize a top surface of the display device DD on the third insulating layer ILD3. The via layer VIA may include organic insulating materials.

FIG. 4 shows an embodiment in which the transistor TR may be connected to one of the gate lines GL and one of the data lines DL. Specifically, the gate electrode GE of the transistor TR may be electrically connected to one of the gate lines GL. In addition, the drain electrode DE of the transistor TR may be electrically connected to one of the data lines DL.

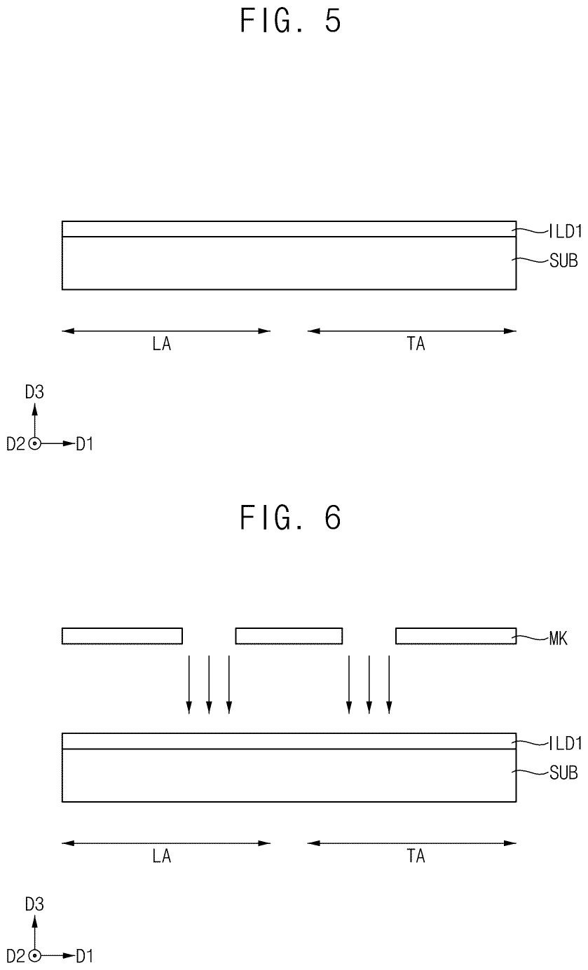

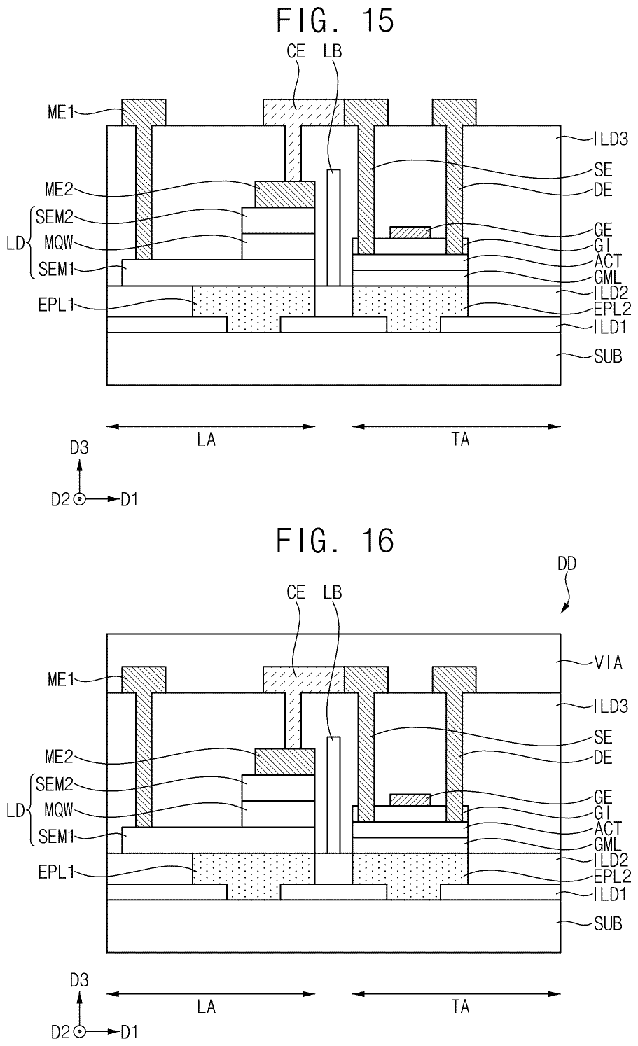

FIGS. 5, 6, 7, 8, 9, 10, 11, 12, 13, 14, 15, and 16 are cross-sectional views of structures that may be formed during an embodiment of a method of manufacturing the display device of FIG. 3.

Referring to FIG. 5, the first insulating layer ILD1 may be formed on the substrate SUB, which includes the light emitting area LA and the driving area TA. For example, the first insulating layer ILD1 may be formed through a chemical vapor deposition (CVD) and may cover an upper surface of the substrate SUB.

Referring further to FIGS. 6 and 7, the first insulating layer ILD1 may be etched through a mask MK disposed on the first insulating layer ILD1. Accordingly, the etching process may remove a portion of the first insulating layer ILD1 to expose at least part of an upper surface of the substrate SUB. Specifically, the first insulating layer ILD1 may be etched to expose separated portions of a top surface of the substrate SUB in the light emitting area LA and the driving area TA.

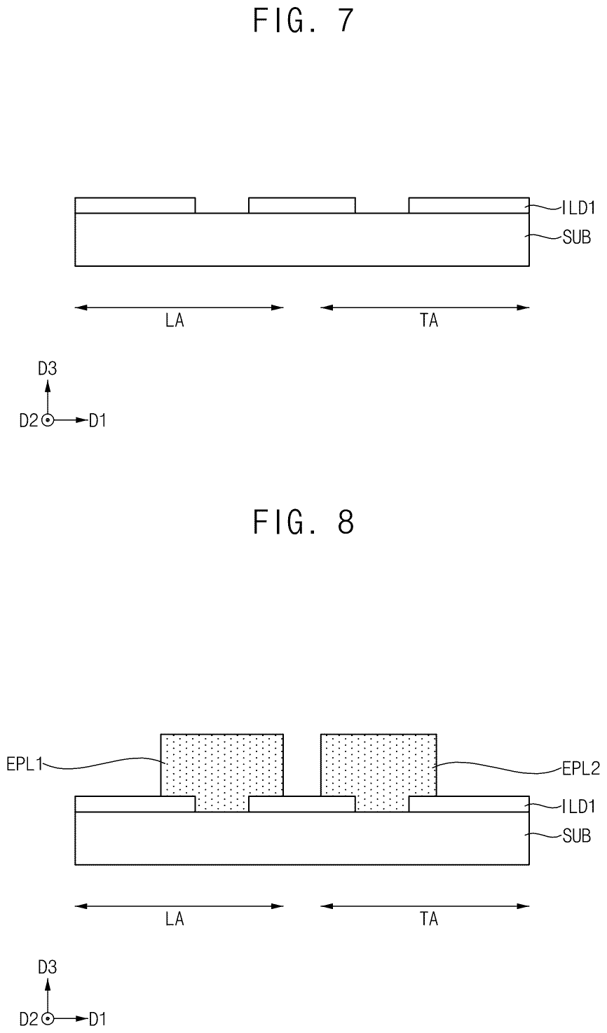

Referring further to FIG. 8, a first epi layer EPL1 may be formed in the light emitting

area LA, and a second epilayer EPL2 may be formed in the driving area TA. Specifically, the first epidermal layer EPL1 may be formed on a top surface of the substrate SUB exposed through an opening in the first insulating layer ILD1 in the light emitting area LA. In addition, the second epi layer EPL2 may be formed on a top surface of the substrate SUB exposed through an opening in the first insulating layer IL2 in the driving area TA. One or more deposition processes may form the first epi layer EPL1 and the second epi layer EPL2.

The first epi layer EPL1 and the second epi layer EPL2 may be disposed on the substrate SUB and the first insulating layer ILD1. The first epi layer EPL1 and the second epi layer EPL2 may cover part of the first insulating layer ILD1. The first epi layer EPL1 and the second epi layer EPL2 may be disposed at the same level on the substrate SUB and may have the same height relative to the substrate SUB as shown in FIG. 8. In an embodiment, the same process may simultaneously form the first epi layer EPL1 and the second epi layer EPL2.

In an embodiment, the first epi layer EPL1 and the second epi layer EPL2 may be

epitaxially grown on the substrate SUB. In other words, by etching the first insulating layer ILD1 to expose the substrate SUB, each of the first epi layer EPL1 and the second epi layer EPL2 may grow epitaxially on an exposed surface of the substrate SUB. As the first epi layer EPL1 and the second epi layer EPL2 grow epitaxial on the substrate SUB, a lattice structure of each of the first epi layer EPL1 and the second epi layer EPL2 may be the same as the lattice structure of the substrate SUB. Accordingly, the light emitting diode LD disposed on the first epi layer EPL1 and the transistor TR disposed on the second epi layer EPL2 may be formed on structures having the same crystallinity.

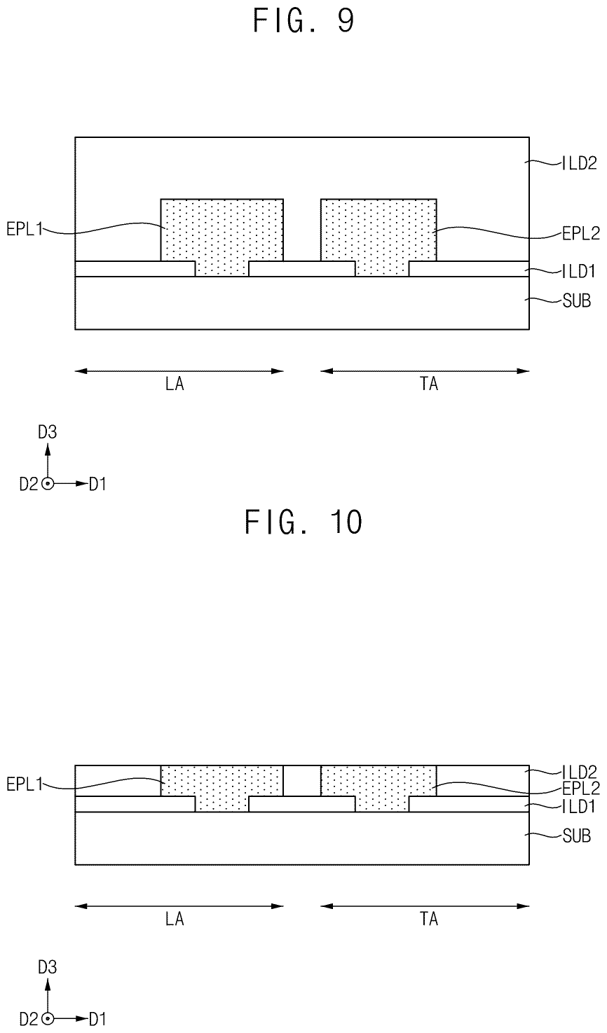

Referring further to FIGS. 9 and 10, the second insulating layer ILD2 may be formed on the first insulating layer ILD1. Specifically, the second insulating layer ILD2 may be formed on the first insulating layer ILD1 and may cover the first epi layer EPL1 and the second epi layer EPL2. After formation, the second insulating layer ILD2 may be polished by a chemically mechanical polishing (CMP) process that removes an upper portion of the second insulating layer ILD2. The chemical mechanical polishing process may polish the second insulating layer ILD2 down to a level of the first epi layer EPL1 and the second epi layer EPL2, at which point, the first epi layer EPL1 and the second epi layer EPL2 may be polished at a same time. As a result, the chemical mechanical polishing process may expose an upper surface of the first epi layer EPL1 and the second epi layer EPL2.

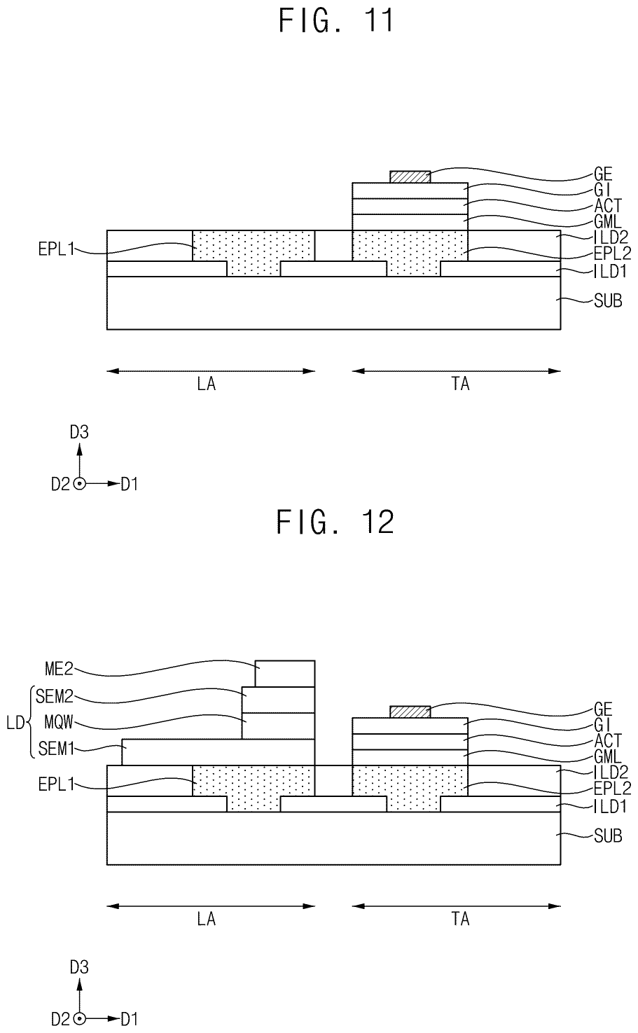

Referring further to FIG. 11, the germanium layer GML, the active layer ACT, the gate insulation pattern GI, and the gate electrode GE may be formed sequentially on the second epi layer EPL2.

The germanium layer GML may be formed on the second epi layer EPL2 after forming the second epi layer EPL2 and before forming the active layer ACT. As a result, the germanium layer GML may be between the second epi layer EPL2 and the active layer ACT in a cross-sectional view.

In an embodiment, the germanium layer GML, the active layer ACT, and the gate electrode GE may be epitaxially grown on the second epi layer EPL2. In other words, lattice structures of the germanium layer GML, the active layer ACT, and the gate electrode GE may sequentially grow epitaxially from the second epi layer EPL2 layer by layer and may have the same lattice structure as the second epi layer EPL2.

Although not shown, in a process of forming the germanium layer GML, the active layer ACT, the gate insulation pattern GI, and the gate electrode GE, a first sacrificial layer covering the first epi layer EPL1 and the second insulating layer ILD2 and selectively exposing the second epi layer EPL2 may be disposed on the first epi layer EPL1 and the second insulating layer ILD2. Accordingly, the process of forming the germanium layer GML, the active layer ACT, the gate insulation pattern GI, and the gate electrode GE may not affect the first epi layer EPL1 and the second insulating layer ILD2. Using the first sacrificial layer, the germanium layer GML, the active layer ACT, the gate insulation pattern GI, and the gate electrode GE may be selectively formed on the second epi layer EPL2. After the germanium layer GML, After the active layer ACT, the gate insulation pattern GI, and the gate electrode GE are formed, the first sacrificial layer may be removed. For example, the first sacrificial layer may include a photoresist material that may be removed without significantly affecting the germanium layer GML, the active layer ACT, the gate insulation pattern GI, and the gate electrode GE.

Referring further to FIG. 12, the first semiconductor layer SEM1, the quantum well layer MQW, the second semiconductor layer SEM2, and the second metal electrode ME2 may be formed sequentially on the first epi layer EPL1. The light emitting diode LD may be formed by the first semiconductor layer SEM1, the quantum well layer MQW, and the second semiconductor layer SEM2.

In an embodiment, the light emitting diode LD may grow epitaxially on the first epi layer EPL1. Specifically, the first semiconductor layer SEM1, the quantum well layer MQW, and the second semiconductor layer SEM2 may grow epitaxially on the first epi layer EPL1. Accordingly, a lattice structure of each of the first semiconductor layer SEM1, the quantum well layer MQW, and the second semiconductor layer SEM2 may have a same lattice structure as the second epi layer EPL2.

Although not shown, a process of forming the first semiconductor layer SEM1, the quantum well layer MQW, the second semiconductor layer SEM2 may employ a second sacrificial layer covering the second epi layer EPL2, the germanium layer GML, the active layer ACT, the gate insulation pattern GI, the gate electrode GE, and a portion of the second insulating layer ILD2 and selectively exposing the first epi layer EPL1. Accordingly, a process may form the first semiconductor layer SEM1, the quantum well layer MQW, the second semiconductor layer SEM2, and the second metal electrode ME2 without affecting the second epi layer EPL2, the germanium layer GML, the active layer ACT, the gate insulation pattern GI, the gate electrode GE, and the second insulating layer ILD2. That is, a process using the second sacrificial layer may selectively form the first semiconductor layer SEM1, the quantum well layer MQW, the second semiconductor layer SEM2, and the second metal electrode ME2 on the first epi layer EPL1. After the first semiconductor layer SEM1, the quantum well layer MQW, the second semiconductor layer SEM2, and the second metal electrode ME2 are formed, the second sacrificial layer may be removed. For example, the second sacrificial layer may include a photoresist material.

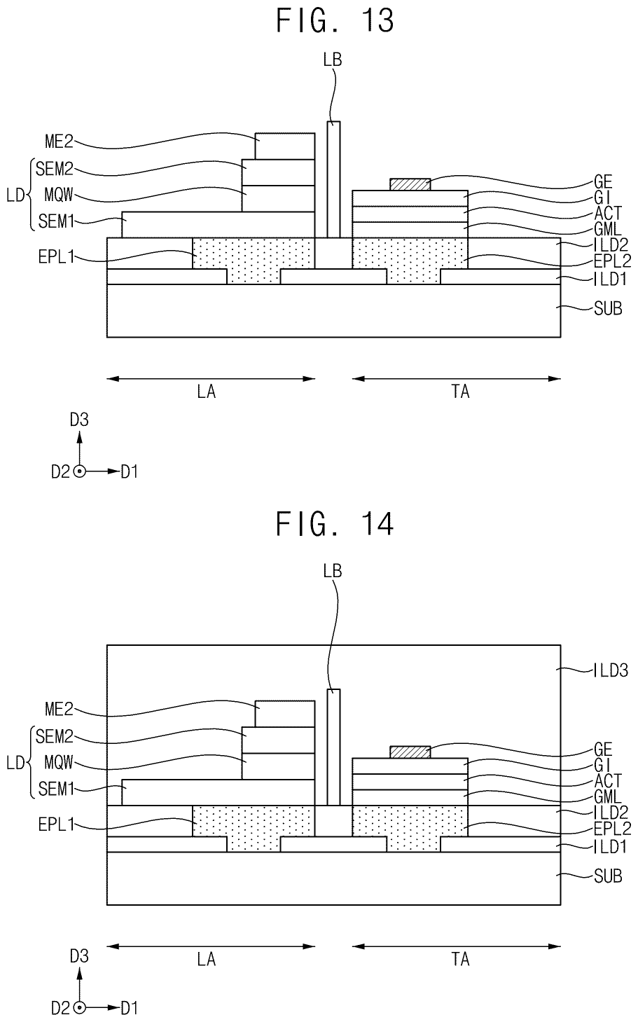

Referring further to FIG. 13, the light barrier LB may be formed on the second insulating layer ILD2. Specifically, the light barrier LB may be formed between the light emitting area LA and the driving area TA in a plan view. The light barrier LB may extend to or beyond the same level or height as the light emitting diode LD. In some embodiments, the light barrier LB may be omitted.

Referring further to FIGS. 14, 15, and 16, a third insulating layer ILD3 may be formed on the second insulating layer ILD2. Specifically, the third insulating layer ILD3 may be formed on the second insulating layer ILD2 and may be formed covering the light emitting diode LD, the light barrier LB, and the gate electrode GE.

The source electrode SE, the drain electrode DE, the connection electrode CE and the first metal electrode ME1 may be formed on the third insulating layer ILD3. Specifically, the source electrode SE and the drain electrode DE may be electrically connected to the active layer ACT through vias penetrating the third insulating layer ILD3. In other words, the source electrode SE and the drain electrode DE may penetrate the third insulating layer ILD3 and may be electrically connected to the source area and the drain area of the active layer ACT, respectively.

The connection electrode CE may be formed on the third insulating layer ILD3 so that the source electrode SE and the second metal electrode ME2 may be electrically connected. Accordingly, the transistor TR may apply an electrical signal to the light emitting diode LD. With the connection electrode CE being disposed on the third insulating layer ILD3 to connect the light emitting diode LD and the transistor TR, the light emitting diode LD and the transistor TR may be spaced apart in the first direction D1 and do not need to overlap in a plan view.

The first metal electrode ME1 may be electrically connected to the light emitting diode LD through a via penetrating the third insulating layer ILD3. Specifically, the first metal electrode ME1 may be electrically connected to the first semiconductor layer SEM1 by penetrating the third insulating layer ILD3.

As a result, by a method of manufacturing of FIGS. 5, 6, 7, 8, 9, 10, 11, 12, 13, 14, 15, and 16, the display device DD including the light emitting diode LD and the transistor TR spaced apart in the first direction D1 may be formed.

Thus, in forming the display device DD including the light emitting diode LD and the transistor TR, a transfer process is not required. That is, as the light emitting diode LD and the transistor TR are formed by processes on the substrate SUB, a transfer process is omitted, so that process cost and process time may be reduced. As a result, a productivity of the manufacturing of the display device DD may be improved.

In addition, the light emitting diode LD and the transistor TR may be disposed at substantially the same level or height on the substrate SUB. Accordingly, compared to a case where the light emitting diode LD is disposed on the transistor TR, a thickness of the display device DD may be thinner.

The present disclosure may be applied to the display device and the electronic device including a same. For example, the present disclosure may be applied to high-resolution smartphones, mobile phones, smart pads, smart watches, tablet PCs, vehicle navigation systems, televisions, computer monitors, laptops, etc.

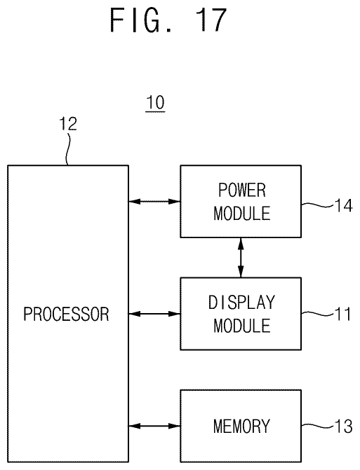

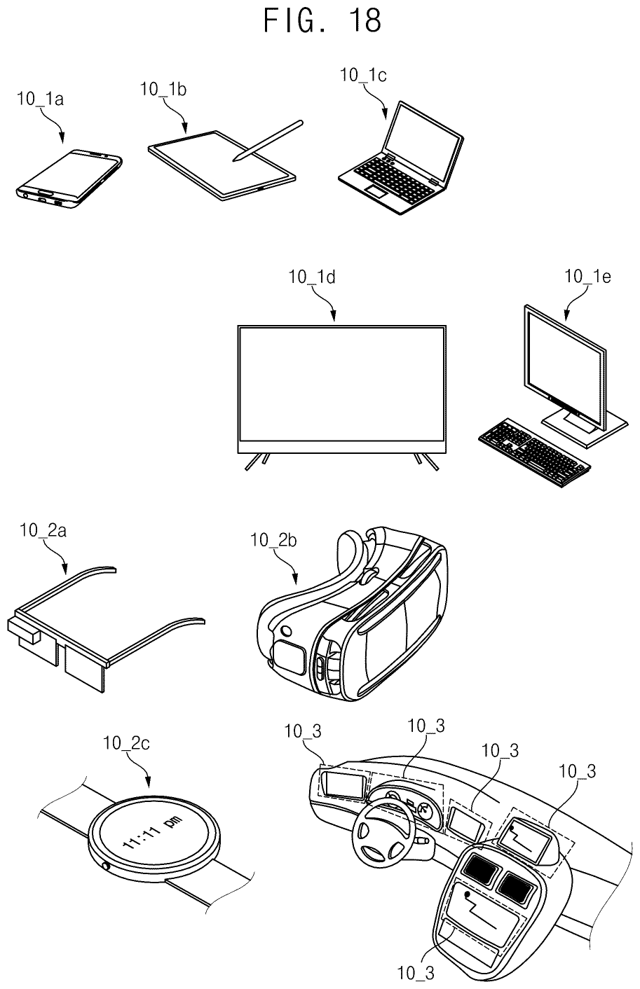

FIG. 17 is block-diagram for showing an electronic device according to an embodiment of the disclosure.

Referring to FIG. 1 and FIG. 17, the display device DD according to the embodiments of present disclosure may be applied to various electronic devices 10. The electronic device 10 according to an embodiment may include the display device DD, and may further include a module or device including additional functions in addition to the display device DD.

The electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for an operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts a power supplied by the power supply module to generate power necessary for an operation of the electronic device 10.

At least one of the components of the electronic device 10 described above may be included in the display device according to the embodiments described above. In addition, some of individual modules functionally included in one module may be included in the display device, and other parts may be provided separately from the display device. For example, the display device DD may include the display module 11, and the processor 12, the memory 13, and the power module 14 may be provided in the form of other devices within the electronic device 10 other than the display device DD.

FIG. 18 shows schematic views of the electronic device according to various embodiments of FIG. 17.

Referring to FIGS. 17 and 18, various electronic devices to which the display device DD according to embodiments is applied may include not only image display electronic devices such as a smart phone 10_1a, a tablet PC 10_1b, a laptop 10_1c, a TV 10_1d, and a desk monitor 10_1e, but also wearable electronic devices including display modules such as smart glasses 10_2a, a head-mounted display 10_2b, and a smart watch 10_2c, and vehicle electronic devices 10_3 including display modules such as a CID (center information display) and a room or rearview mirror display placed on a dashboard, center fascia, or dashboard of an automobile.

However, this is exemplary, and the electronic device 10 according to embodiments of the present disclosure is not limited thereto. For example, the electronic device 10 may be implemented as a mobile phone, a video phone, a smart pad, a smart watch, a tablet PC, a vehicle display, a computer monitor, a notebook computer, a head-mounted display device, etc. In addition, the electronic device 10 may be a television, a monitor, a notebook computer, or a tablet. In addition, the electronic device 10 may be an automobile.

While the disclosure has been particularly shown and described with reference to embodiments thereof, it will be understood by those of ordinary skill in the art that various changes in form and details may be made therein without departing from the spirit or scope of the disclosure as defined by the following claims.

What is claimed is:

1. A display device comprising:
a substrate including a light emitting area and a driving area spaced apart from the light emitting area in a plan view;
a first epi layer disposed in the light emitting area on the substrate;
a light emitting diode disposed in the light emitting area and disposed on the first epi layer;
a second epi layer disposed in the driving area on the substrate;
a transistor disposed in the driving area and on the second epi layer; and
a connection electrode that electrically connects the light emitting diode and the transistor.

2. The display device of claim 1, further comprising:
a metal electrode disposed on the light emitting diode and electrically connected to the light emitting diode,
wherein the connection electrode is connected to the metal electrode.

3. The display device of claim 1, wherein
the light emitting diode includes a first semiconductor layer, a quantum well layer, and a second semiconductor layer,
the first semiconductor layer is an n-type semiconductor, and
the second semiconductor layer is a p-type semiconductor.

4. The display device of claim 1, further comprising:
a germanium layer disposed between the second epi layer and the transistor.

5. The display device of claim 4, wherein
the transistor includes an active layer disposed on the germanium layer, and
a lattice constant of the germanium layer is greater than a lattice constant of the active layer.

6. The display device of claim 5, wherein the active layer is disposed lower than the quantum well layer of the light emitting diode in a cross-sectional view.

7. The display device of claim 5, wherein the light emitting diode and the active layer are spaced apart from each other in a plan view.

8. The display device of claim 1, further comprising:
a light barrier disposed between the light emitting diode and the transistor in a plan view.

9. The display device of claim 8, wherein the light barrier is disposed on the substrate and extends to a same level as the light emitting diode.

10. The display device of claim 1, wherein the substrate includes at least one of silicon, silicon germanium, silicon carbide, and sapphire.

11. The display device of claim 1, wherein the first epi layer and the second epi layer include silicon.

12. The display device of claim 1, wherein the first epi layer and the second epi layer are disposed at a same level on the substrate.

13. A method of manufacturing a display device comprising:
forming a first insulating layer on a substrate including a light emitting area and a driving area spaced apart from the light emitting area in a plan view;
exposing an upper surface of the substrate in the light emitting area and the driving area by etching the first insulating layer;
forming a first epi layer on the upper surface where exposed in the light emitting area and forming a second epi layer on the upper surface where exposed in the driving area;
forming a transistor on the second epi layer; and
forming a light emitting diode on the first epi layer.

14. The method of claim 13, further comprising:
after forming the light emitting diode on the first epi layer, forming a connection electrode that electrically connects the light emitting diode and the transistor.

15. The method of claim 13, wherein the first epi layer and the second epi layer are formed together in a same process.

16. The method of claim 13, wherein forming the first epi layer in the light emitting area and forming the second epi layer in the driving area includes:
depositing the first epi layer in the light emitting area and depositing the second epi layer in the driving area;
forming a second insulating layer covering the first epi layer and the second epi layer; and
polishing the second insulating layer to expose the first epi layer and the second epi layer from the second insulating layer.

17. The method of claim 13, further comprising:
after forming the second epi layer and before forming the transistor, forming a germanium layer on the second epi layer.

18. The method of claim 17, wherein the germanium layer is formed by epitaxial growth on the second epi layer.

19. The method of claim 13, wherein the light emitting diode is formed by epitaxial growth on the first epi layer, and
the transistor is formed by epitaxial growth on the second epi layer.

20. An electronic device comprising:
a display device; and
a processor configured to drive the display device, and
wherein the display device includes:
a substrate including a light emitting area and a driving area spaced apart from the light emitting area in a plan view;
a first epi layer disposed in the light emitting area on the substrate;
a light emitting diode disposed in the light emitting area and disposed on the first epi layer;
a second epi layer disposed in the driving area on the substrate;
a transistor disposed in the driving area and on the second epi layer; and
a connection electrode that electrically connects the light emitting diode and the transistor.
